(19) United States
(12) Patent Application Publication
(10) Pub. No.: US 2026/0123349 A1
(43) Pub. Date: Apr. 30, 2026

(54) RIM VENTED SUSCEPTOR

(71) Applicant: Applied Materials, Inc., Santa Clara, CA (US)

(72) Inventors: John NEWMAN, Chandler, AZ (US); Hui CHEN, Tempe, AZ (US); Xinning LUAN, Tempe, AZ (US); Shawn Joseph BONHAM, Mesa, AZ (US)

(21) Appl. No.: 18/932,875

(22) Filed: Oct. 31, 2024

(51) Int. Cl. H01L 21/687; C23C 16/458

(52) U.S. Cl. CPC H10P 72/7611; C23C 16/4581

(57) ABSTRACT

A susceptor defining an axial direction, a radial direction, and a circumferential direction is provided. The susceptor includes a support surface for a substrate. The susceptor further includes a rim extending around a periphery of the support surface. The rim defines a plurality of pockets spaced apart from one another along the circumferential direction. The rim further defines one or more vents at each respective pocket of the plurality of pockets.

### BACKGROUND

### Field

Examples described herein generally relate a susceptor to be used in an epitaxy deposition process and, more particularly, to a susceptor having a support surface for a substrate (e.g, substrate) and a rim (e.g., raised relative to the support surface) extending around a periphery of the support surface and defining a plurality of vents to improve uniformity of the growth rate of silicon on the substrate.

### Description of the Related Art

A vapor deposition process is used in semiconductor substrate processing, along with other processes, for epitaxially depositing a thin layer (generally, less than 10 micron) on a substrate. During the deposition process, the substrate is positioned on a support surface of a susceptor and a film (e.g. epitaxial film) is deposited onto the substrate. However, the film is not deposited onto the substrate at a uniform rate in all directions and, as a result, the thickness of the film deposited onto the substrate is non-uniform.

Accordingly, there is need for apparatuses that enable uniform film deposition.

### SUMMARY

In one aspect, a susceptor is provided. The susceptor defines a coordinate system including an axial direction, a radial direction, and a circumferential direction. The susceptor includes: a support surface for a substrate; and a rim extending around a periphery of the support surface, the rim defining a plurality of pockets spaced apart from one another along the circumferential direction, the rim further defining one or more vents at each respective pocket of the plurality of pockets.

In another aspect, a processing chamber is provided. The processing chamber includes a chamber body in fluid communication with one or more gas sources. The processing chamber further includes a substrate support assembly including a susceptor defining a coordinate system comprising an axial direction, a radial direction, and a circumferential direction. The susceptor includes: a support surface for a substrate; and a rim extending around a periphery of the support surface, the rim defining a plurality of pockets spaced apart from one another along the circumferential direction, the rim further defining one or more vents at each respective pocket of the plurality of pockets.

In yet another aspect, a processing system is provided. The processing system includes a processing chamber including a chamber body in fluid communication with one or more gas sources. The processing chamber further includes a substrate support assembly including a susceptor defining a coordinate system comprising an axial direction, a radial direction, and a circumferential direction. The susceptor includes: a support surface for a substrate; and a rim extending around a periphery of the support surface, the rim defining a plurality of pockets spaced apart from one another along the circumferential direction, the rim further defining one or more vents at each respective pocket of the plurality of pockets.

### BRIEF DESCRIPTION OF THE DRAWINGS

So that the manner in which the above recited features of the present disclosure can be understood in detail, a more particular description, briefly summarized above, may be had by reference to examples, some of which are illustrated in the appended drawings. It is to be noted, however, that the appended drawings illustrate only some examples and are therefore not to be considered limiting of the scope of this disclosure, for the disclosure may admit to other equally effective examples.

FIG. 1 is a schematic top-view diagram of an example multi-chamber processing system according to some embodiments of the present disclosure.

FIG. 2 is a cross-sectional view of a thermal processing chamber that may be used to perform epitaxial growth according to some embodiments of the present disclosure.

FIG. 3 is a plan view of a susceptor with a substrate placed on a support surface of the susceptor according to some embodiments of the present disclosure.

FIG. 4A is top, perspective view of a susceptor according to some embodiments of the present disclosure.

FIG. 4B is a plan view of a susceptor according to some embodiments of the present disclosure.

FIG. 4C is a close-up view of a portion of the susceptor depicted in FIG. 4A according to some embodiments of the present disclosure.

FIG. 4D is a close-up view of a portion of the susceptor depicted in FIG. 4B according to some embodiments of the present disclosure.

FIG. 4E is a cross-sectional view of a pocket of the susceptor of FIG. 4A according to some embodiments of the present disclosure.

FIG. 4F is a close-up of a portion of the pocket of the susceptor of FIG. 4E according to some embodiments of the present disclosure.

FIG. 5A is top, perspective view of a susceptor according to some embodiments of the present disclosure.

FIG. 5B is a plan view of a susceptor according to some embodiments of the present disclosure.

FIG. 5C is a close-up view of a portion of the susceptor depicted in FIG. 5A according to some embodiments of the present disclosure.

FIG. 5D is a close-up view of a portion of the susceptor depicted in FIG. 5B according to some embodiments of the present disclosure.

FIG. 5E is a cross-sectional view of a pocket of the susceptor of FIG. 4A according to some embodiments of the present disclosure.

FIG. 5F is a close-up of a portion of the pocket of the susceptor of FIG. 5E according to some embodiments of the present disclosure.

FIG. 6A is top, perspective view of a susceptor according to some embodiments of the present disclosure.

FIG. 6B is a plan view of a susceptor according to some embodiments of the present disclosure.

FIG. 6C is a close-up view of a portion of the susceptor depicted in FIG. 6A according to some embodiments of the present disclosure.

FIG. 6D is a close-up view of a portion of the susceptor depicted in FIG. 4B according to some embodiments of the present disclosure.

FIG. 6E is a cross-sectional view of a pocket of the susceptor of FIG. 6A according to some embodiments of the present disclosure.

FIG. 7A is a close-up view of a pocket of a susceptor according to some embodiments of the present disclosure.

FIG. 7B is another view of the pocket of the susceptor in FIG. 7A according to some embodiments of the present disclosure.

FIG. 8A is a close-up view of a pocket of a susceptor according to some embodiments of the present disclosure.

FIG. 8B is another view of the pocket of the susceptor in FIG. 8A according to some embodiments of the present disclosure.

To facilitate understanding, identical reference numerals have been used, wherever possible, to designate identical elements that are common to the figures.

### DETAILED DESCRIPTION

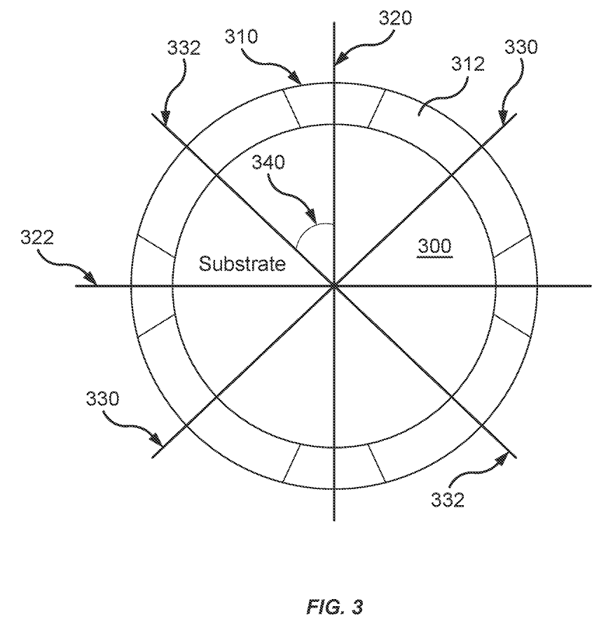

Generally, examples described herein relate to a susceptor to hold a substrate thereon for semiconductor substrate processing. As will be discussed in FIG. 3, a film may be deposited onto a substrate (e.g., supported by a susceptor) at different rates along different axes, which results in the thickness of the film being non-uniform. Existing techniques may rotate the substrate to minimize the non-uniformity of the thickness of the film. As discussed herein, susceptors according to the present disclosure include a rim defining a plurality of vents that provide an exhaust path for process gases and/or byproducts associated with processing the substrate. These vents in the rim of the susceptors disclosed herein modulate the gas flow (e.g, of process gases and/or byproducts) to eliminate (or at least minimize) the non-uniformity of the thickness of the film along different axes without needing to rotating the substrate.

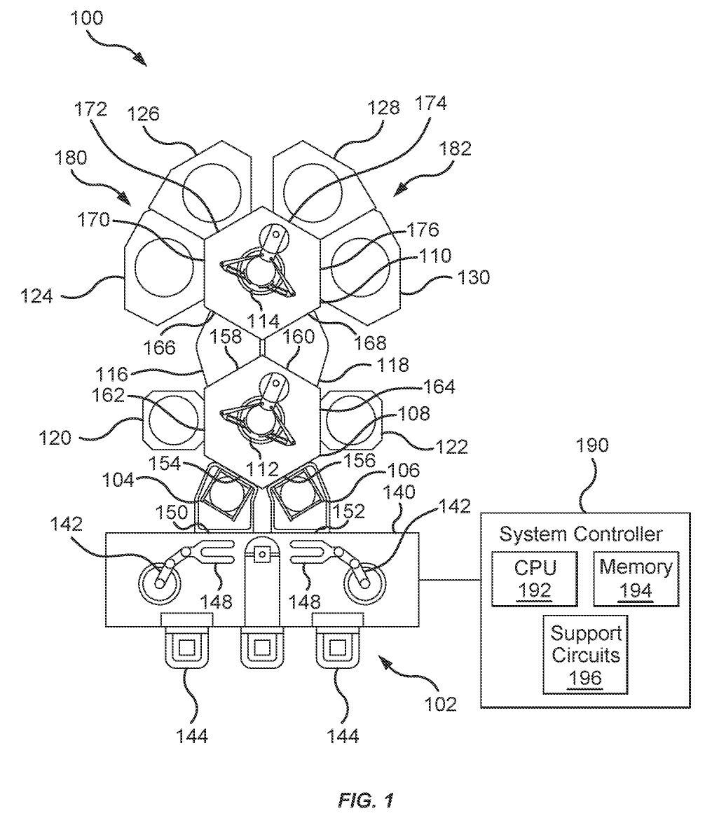

FIG. 1 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers in a low pressure (e.g., less than or equal to about 300 Torr) or vacuum environment without breaking the low pressure or vacuum environment between various processes performed on the substrates in the processing system 100. Accordingly, the processing system 100 may provide for an integrated solution for some processing of substrates.

Examples of a processing system that may be suitably modified in accordance with the teachings provided herein include the Endura^{®}, Producer^{®} or Centura^{®} integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of substrates. The docking station 140 is configured to accept one or more front opening unified pods (FOUPs) 144. In some examples, each factory interface robot 142 generally comprises a blade 148 disposed on one end of the respective factory interface robot 142 configured to transfer the substrates from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough; otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a substrate from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 154 or 156. The transfer robot 112 is then capable of transferring the substrate to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the substrate in the holding chamber 116 or 118 through the port 166 or 168 and is capable of transferring the substrate to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 122 can be capable of performing a cleaning process; the processing chamber 120 can be capable of performing an etch process; and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

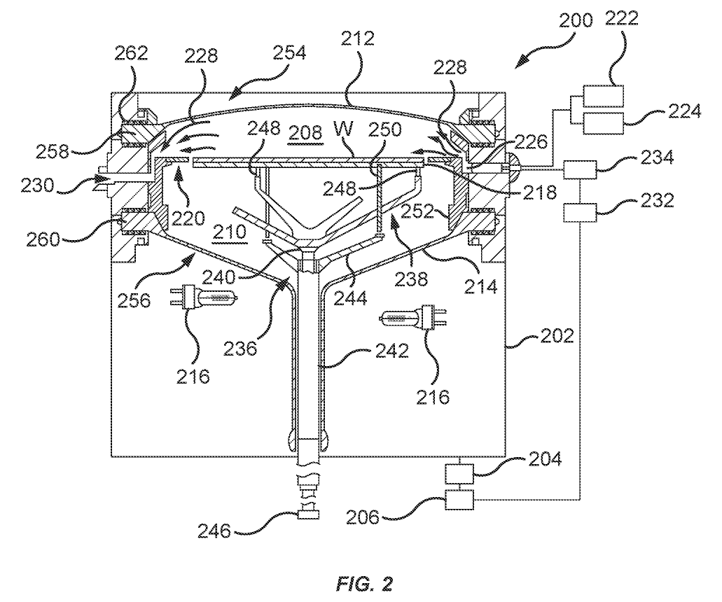

FIG. 2 is a cross-sectional view of a processing chamber 200 that may be used to perform epitaxial growth. The processing chamber 200 may be any one of processing chambers 120, 122, 124, 126, 128, 130 from FIG. 1. Non-limiting examples of the suitable processing chambers that may be modified according to embodiments disclosed herein may include epitaxial deposition chambers which are commercially available from Applied Materials, Inc. of Santa Clara, Calif. The processing chamber 200 may be added to a CENTURA® integrated processing system available from Applied Materials, Inc., of Santa Clara, Calif. While the processing chamber 200 is described below to be utilized to practice various embodiments described herein, other semiconductor processing chambers from different manufacturers may also be used to practice the embodiment described in this disclosure.

The processing chamber 200 includes a chamber body 202, a support system 204, and a controller 206. The chamber body 202 includes an upper portion 208 and a lower portion 210. The upper portion 208 includes the area within the chamber body 202 between an upper dome 212 and a substrate W. The lower portion 210 includes the area within the chamber body 202 between a lower dome 214 and the bottom of the substrate W. Deposition processes generally occur on the upper surface of the substrate W within the upper portion 208.

The support system 204 includes components used to execute and monitor pre-determined processes, such as the growth of epitaxial films in the processing chamber 200. A controller 206 is coupled to the support system 204 and is adapted to control the processing chamber 200 and support system 204. The controller 206 may be the system controller 190 or a controller controlled by the system controller 190 for controlling processes within the processing chamber 200.

The processing chamber 200 includes a plurality of heat sources, such as lamps 216, which are adapted to provide thermal energy to components positioned within the processing chamber 200. For example, the lamps 216 may be adapted to provide thermal energy to the substrate W, a susceptor 218, and/or a preheat ring 220. The lower dome 214 may be formed from an optically transparent material, such as quartz, to facilitate the passage of thermal radiation therethrough. It is contemplated that lamps 216 may be positioned to provide thermal energy through the upper dome 212 as well as the lower dome 214.

The chamber body 202 includes a plurality of plenums formed therein. The plenums are in fluid communication with one or more gas sources 222, such as a carrier gas, and one or more precursor sources 224, such as deposition gases and dopant gases. For example, a first plenum 226 may be adapted to provide a deposition gas 228 therethrough into the upper portion 208 of the chamber body 202, while a second plenum 230 may be adapted to exhaust the deposition gas 228 from the upper portion 208. In such a manner, the deposition gas 228 may flow parallel to an upper surface of the substrate W.

In cases where a liquid precursor is used, the processing chamber 200 may include a liquid vaporizer 232 in fluid communication with a liquid precursor source 234. The liquid vaporizer 232 is be used for vaporizing liquid precursors to be delivered to the processing chamber 200. While not shown, it is contemplated that the liquid precursor source 234 may include, for example, one or more ampules of precursor liquid and solvent liquid, a shut-off valve, and a liquid flow meter (LFM).

A substrate support assembly 236 is positioned in the lower portion 210 of the chamber body 202. The substrate support assembly 236 is illustrated supporting a substrate W in a processing position. The substrate support assembly 236 includes a susceptor support shaft 238 formed from an optically transparent material and the susceptor 218 supported by the susceptor support shaft 238. A shaft 240 of the susceptor support shaft 238 is positioned within a shroud 242 to which lift pin contacts 244 are coupled. The susceptor support shaft 238 is rotatable in order to facilitate the rotation of the substrate W during processing. Rotation of the susceptor support shaft 238 is facilitated by an actuator 246 coupled to the susceptor support shaft 238. The shroud 242 is generally fixed in position, and therefore, does not rotate during processing. Support pins 248 couple the susceptor support shaft 238 to the susceptor 218.

Lift pins 250 are offset relative to the susceptor support shaft 238. The lift pins 250 are vertically actuatable and are adapted to contact the underside of the substrate W to lift the substrate W from a processing position (as shown) to a substrate removal position.

The preheat ring 220 is removably disposed on a lower liner 252 that is coupled to the chamber body 202. The preheat ring 220 is disposed around the internal volume of the chamber body 202 and circumscribes the substrate W while the substrate W is in a processing position. The preheat ring 220 facilitates preheating of a process gas as the process gas enters the chamber body 202 through the first plenum 226 adjacent to the preheat ring 220.

A central window portion 254 of the upper dome 212 and a bottom portion 256 of the lower dome 214 may be formed from an optically transparent material such as quartz. A peripheral flange 258 of the upper dome 212, which engages the central window portion 254 around a circumference of the central window portion 254, a peripheral flange 260 of the lower dome 214, which engages the bottom portion 256 around a circumference of the bottom portion 256, may all be formed from an opaque quartz to protect O-rings 262 in proximity to the peripheral flanges from being directly exposed to the heat radiation. The peripheral flange 258 may be formed of an optically transparent material such as quartz.

FIG. 3 depicts a substrate 300 disposed on a susceptor 310 according to some embodiments of the present disclosure. The susceptor 310 includes a support surface (e.g., positioned underneath substrate 300) on which the substrate 300 is positioned. The susceptor 310 further includes a rim 312 extending around a periphery of the support surface and generally elevated (e.g., raised) relative to the support surface. In this manner, the rim 312 may contain the substrate 300 on the support surface such that the substrate 300 does not move (e.g., slide) on the support surface.

During processing of the substrate 300, a film may be deposited onto the substrate 300. However, the rate at which the film is deposited onto the substrate 300 is non-uniform. For instance, the film may be deposited onto the substrate 300 at faster rate along axes (e.g., first axis 320 and second axis 322 perpendicular to the first axis 320) of a first coordinate system than along axes (e.g., third axis 330 and fourth axis 332 perpendicular to the third axis 330) of a second coordinate system that shares a common origin with the first coordinate system and is offset from the first coordinate system by an angle 340 (e.g., about forty-five degrees). This results in the thickness of the film deposited onto the substrate 300 being non-uniform across the surface of the substrate 300. As will be discussed herein, the present disclosure is directed to a susceptor having a rim defining a plurality of vents to provide a path for process gases and byproducts to be evacuated from the susceptor resulting in a more uniform rate of deposition of the film onto the substrate 300.

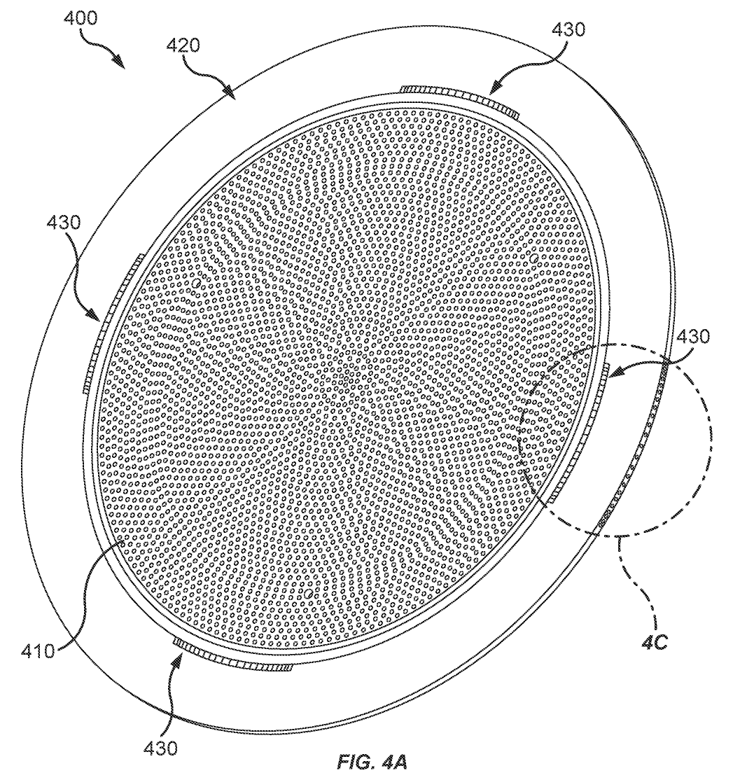

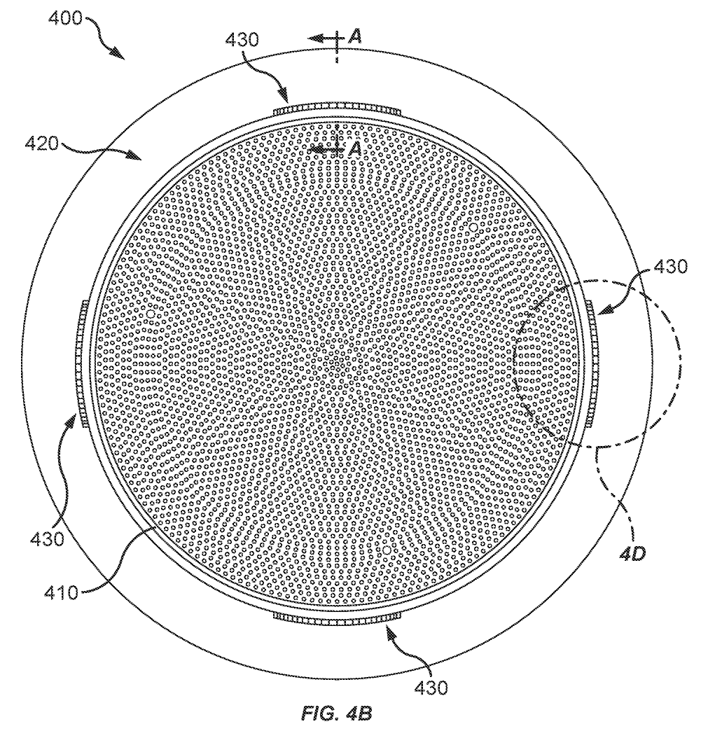

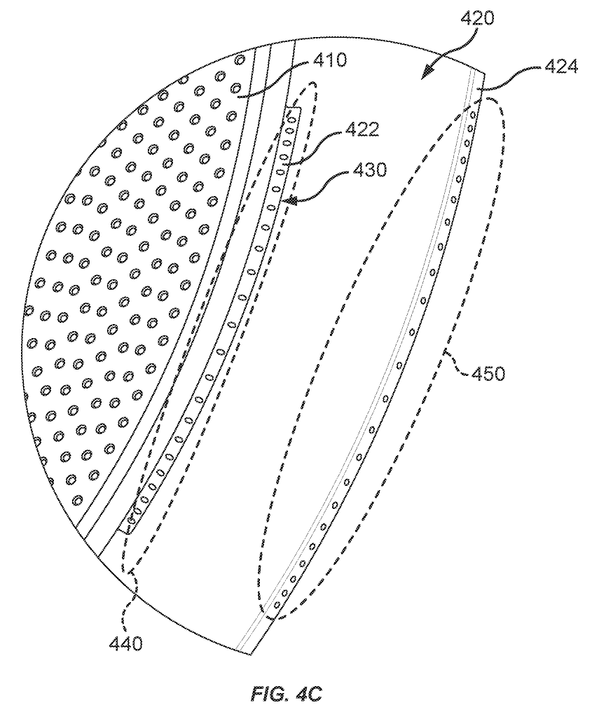

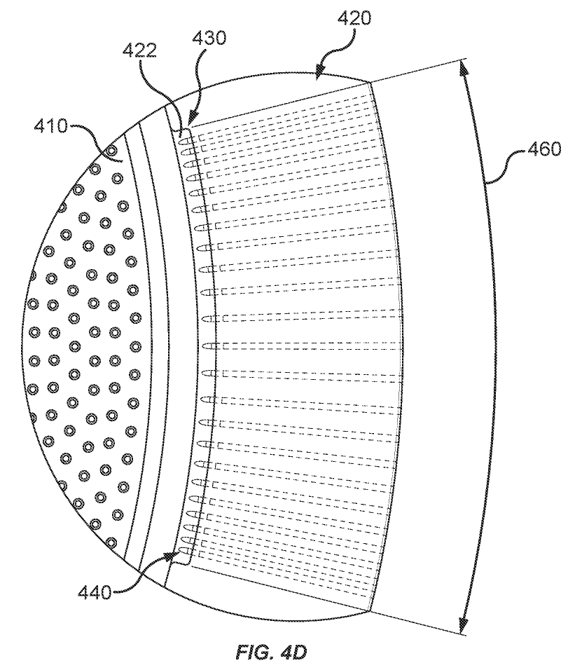

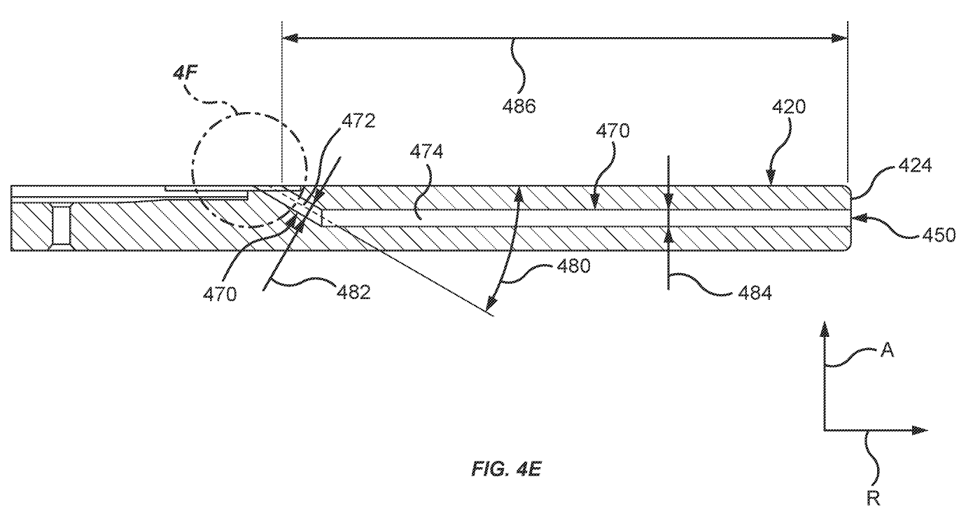

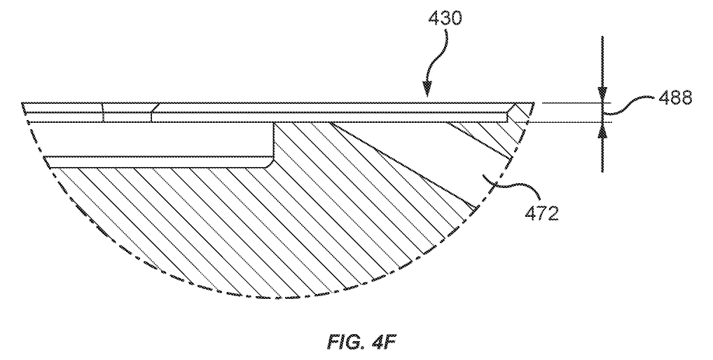

FIGS. 4A-4F illustrate a susceptor 400 according to some embodiments of the present disclosure. The susceptor 400 defines a coordinate system including an axial direction A, a radial direction R, and a circumferential direction (not shown).

As illustrated in FIGS. 4A and 4B, the susceptor 400 includes a support surface 410 for a substrate. In some embodiments, the support surface 410 may include raised bumps arranged in a grid (or mesh) pattern as shown. In alternative embodiments, the support surface 410 may be solid.

The susceptor 400 includes a rim 420 extending around the periphery (e.g., outermost edge) of the support surface 410 and along the circumferential direction. As illustrated, the rim 420 defines a plurality of pockets 430 (e.g., recesses) spaced apart from one another along the circumferential direction of the susceptor 400. For instance, in some embodiments, the pockets 430 are spaced apart from one another by about 90 degrees along the circumferential direction, as measured from a center of each pocket 430.

As illustrated in FIG. 4C, the rim 420 may define a first plurality of openings 440 (e.g., inlets) that are positioned within each respective pocket of the plurality of pockets 430. For example, the plurality of openings 440 may be defined in a first surface 422 of the rim 420 that is elevated (e.g., spaced apart from along the axial direction A) relative to the support surface 410. Also, as illustrated, a second surface 424 of the rim 420 that is spaced apart (e.g., along the radial direction R) from the first surface 422 of the rim 420 and is substantially perpendicular (e.g., within about 5 degrees of perpendicular, within about 1 degree of perpendicular) to the first surface 422 of the rim 420 may define a second plurality of openings 450. The second plurality of openings 450 may be spaced apart (e.g., along the circumferential direction) from one another and each respective opening of the second plurality of openings 450 may generally be aligned (e.g., along the circumferential direction) with a respective opening of the first plurality of openings 440. Stated another way, and as illustrated in FIG. 4D, the first plurality of openings 440 and the second plurality of openings 450 may generally be arranged along an arc 460 that extends along the circumferential direction of the susceptor 400 and generally corresponds to a width of the respective pocket 430 in which the openings 440, 450 are positioned. In some embodiments, a width of the arc 460 may range from 30 degrees to 45 degrees. The arc 460 illustrated may be an outside arc associated with the respective pocket 430 and, in some embodiments, the outside arc may be substantially the same (e.g., within about 5 degrees, within about 1 degree) as an inside arc associated with the respective pocket 430.

As illustrated in FIG. 4E, the rim 420 of the susceptor 400 defines a plurality of channels 470 (only one shown for simplicity). Each respective channel of the plurality of channels 470 extends from a respective opening of the first plurality of openings 440 to a respective opening of the second plurality of openings 450. Furthermore, each respective channel of the plurality of channels 470 includes a first portion 472 and a second portion 474. The first portion 472 of each respective channel extends (e.g., downward along the axial direction A) from a respective opening of the first plurality of openings 440. The second portion 474 of each respective channel may extend from the first portion 472 to a respective opening of the second plurality of openings 450.

It should be understood that each of the channels 470 connects a respective opening of the first plurality of openings 440 to a respective opening of the second plurality of openings 450 as described above to form a vent in the rim 420 of the susceptor 400. In this manner, the plurality of vents defined in the rim 420 provide an exhaust path for gases and/or byproducts associated with processing of a substrate positioned on the support surface 410 (FIG. 4A) of the susceptor 400. Furthermore, venting the gases and byproducts in this manner (e.g., through the plurality of vents defined in the rim 420) improves the uniformity of the rate at which film is deposited onto the substrate. More specifically, the vents defined in the rim 420 modulate the gas flow (e.g., of process gases and/or byproducts) such that the deposition rate of the film may be uniform along all axes (e.g., the axes of the first and second coordinate systems discussed above with reference to FIG. 3)

In some embodiments, the first portion 472 of each respective channel extends at an angle 480 relative the radial direction R of the susceptor 400. In some embodiments, the angle 480 may range from 30 degrees to 90 degrees.

In some embodiments, a diameter 482 of the first portion 472 of one or more of the plurality of channels 470 may range from 0.01 inches to 0.05 inches. Alternatively, or additionally, a diameter 484 of the second portion 474 of one or more of the plurality of channels 470 may range from 0.04 inches to 0.10 inches.

In some embodiments, a distance 486 (e.g., measured along the radial direction R) from a center of each respective opening of the first plurality of openings 440 to the second surface 424 that defines the second plurality of openings 450.

In some embodiments, a height 488 of the pocket 430 may range from 0.005 inches to 0.020 inches.

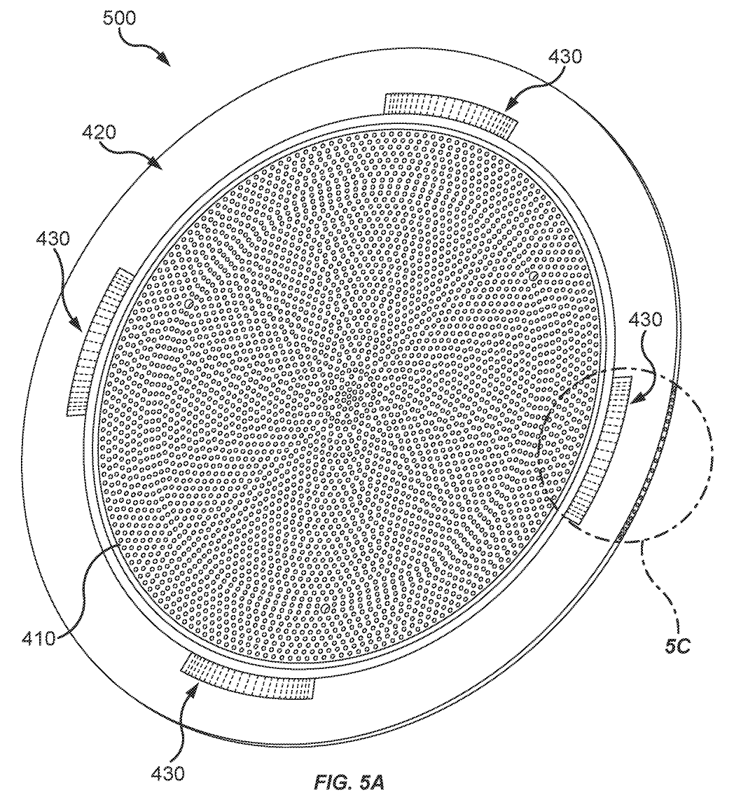

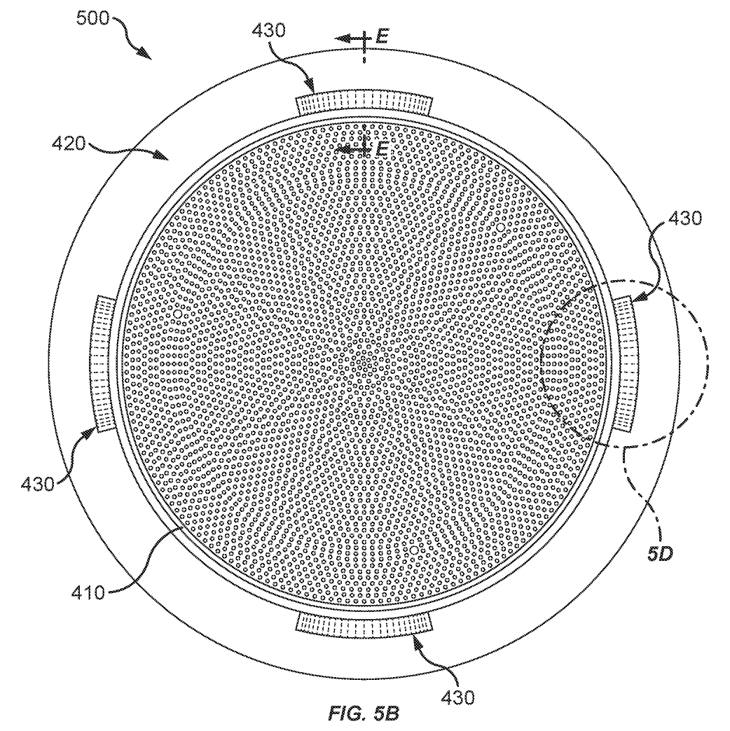

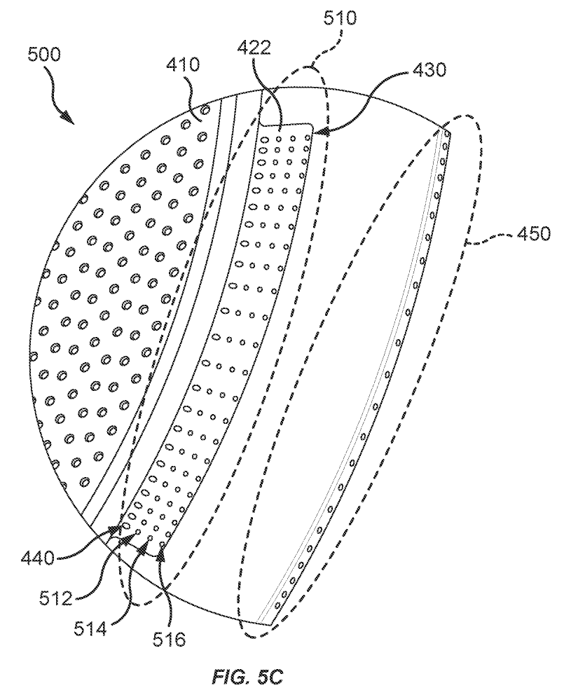

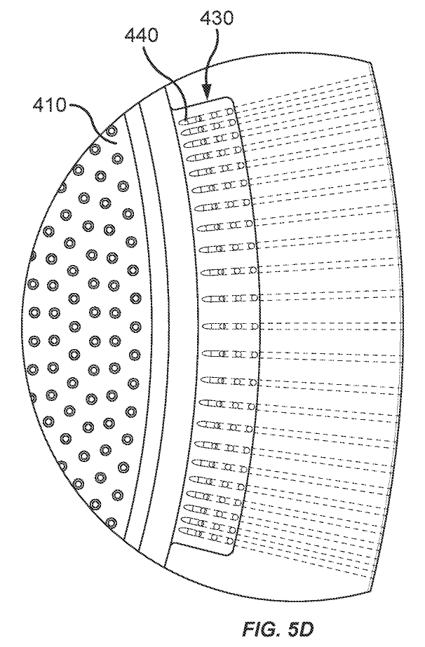

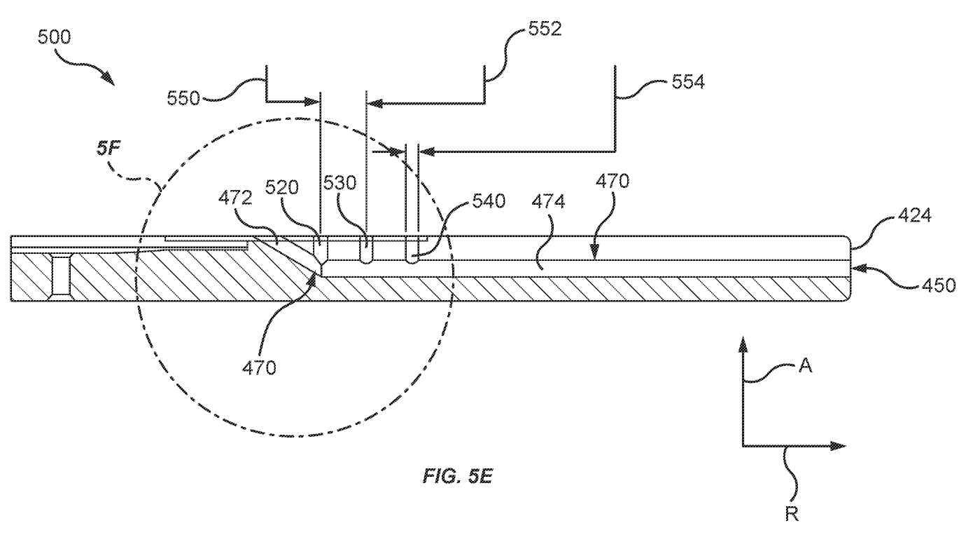

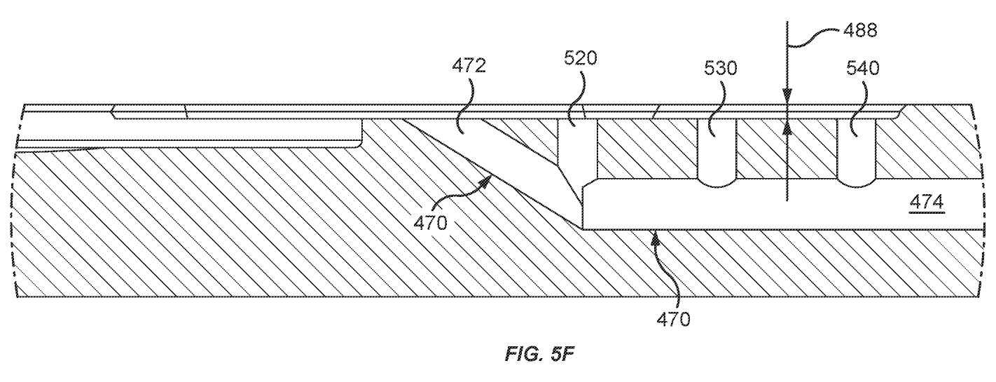

FIGS. 5A-5F illustrate a susceptor 500 according to some embodiments of the present disclosure. The susceptor 500 is substantially similar to the susceptor 400 discussed above with reference to FIGS. 4A-4F and, for simplicity, reference numbers used to denote features of the susceptor 400 of FIGS. 4A-4F are reused for features of the susceptor 500 of FIGS. 5A-5F that are the same. Accordingly, the discussion of the susceptor 500 of FIGS. 5A-5F will be limited to the features thereof that are different from the susceptor 400 of FIGS. 4A-4F.

As illustrated in FIG. 5C, each of the pockets 430 defined in the rim 420 of the susceptor 400 may include a first plurality of openings 510. The first plurality of openings 510 may include openings 440 (e.g., discussed above with reference to FIG. 4D) as a first subset of the first plurality of openings 510. Additionally, the first plurality of openings 510 may include openings 512 as a second subset of the first plurality of openings 510, openings 514 as a third subset of the first plurality of openings 510, and openings 516 as a fourth subset of the first plurality of openings 510.

As illustrated, openings 440 may be spaced apart from one another along the circumferential direction, openings 512 may be spaced apart from one another along the circumferential direction, openings 514 may be spaced apart from one another along the circumferential direction, and openings 516 may be spaced apart from one another along the circumferential direction. Furthermore, the first subset (e.g., openings 440) of the first plurality of openings 510, the second subset (e.g,. openings 512) of the first plurality of openings 510, the third subset (e.g., openings 514) of the first plurality of openings 510, and the fourth subset (e.g., openings 516) of the first plurality of openings 510 may be spaced apart from one another along the radial direction R as shown, with the first subset (e.g., openings 440) being closer to a center of the susceptor 400 than the second subset (e.g., openings 512), the third subset (e.g., openings 514), and the fourth subset (e.g., openings 516).

As illustrated in FIG. 5E, the susceptor 400 may define a third plurality of channels 520 (only one shown), a fourth plurality of channel 530 (only one shown), and a fifth plurality of channels 540 (only one shown). Each respective channel in the third plurality of channels 520 may extend from a respective opening of openings 512 and along the axial direction A to the second portion 474 of a respective channel of the plurality of channels 470. Each respective channel in the fourth plurality of channels 530 may extend from a respective opening of openings 514 and along the axial direction A to the second portion 474 of a respective channel of the plurality of channels 470. Each respective channel in the fifth plurality of channels 540 may extend from a respective opening of openings 516 along the axial direction A to the second portion 474 of a respective channel of the plurality of channels 470. In this manner, the each of openings 512, 514, and 516 may connected (e.g., via channels 520, 530, 540) to a respective channel of the plurality of channels 470 to create additional vents for process gases and/or byproducts associated with processing the substrate to exit the susceptor 500.

In some embodiments, openings 512, openings 514, and openings 516 may have a diameter 550, 552, 554, respectively, ranging from 0.01 inches to 0.05 inches.

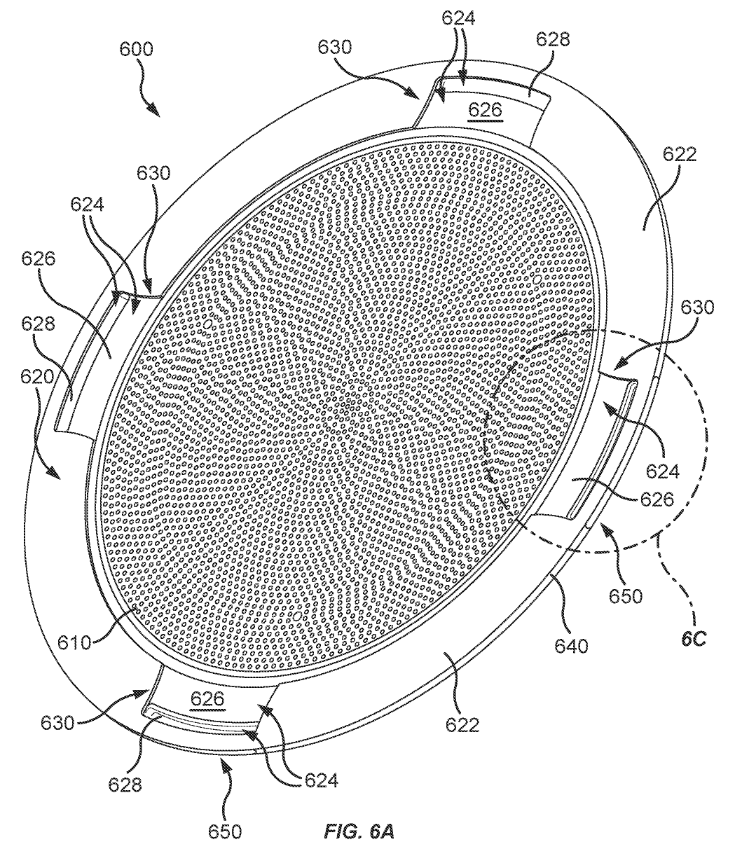

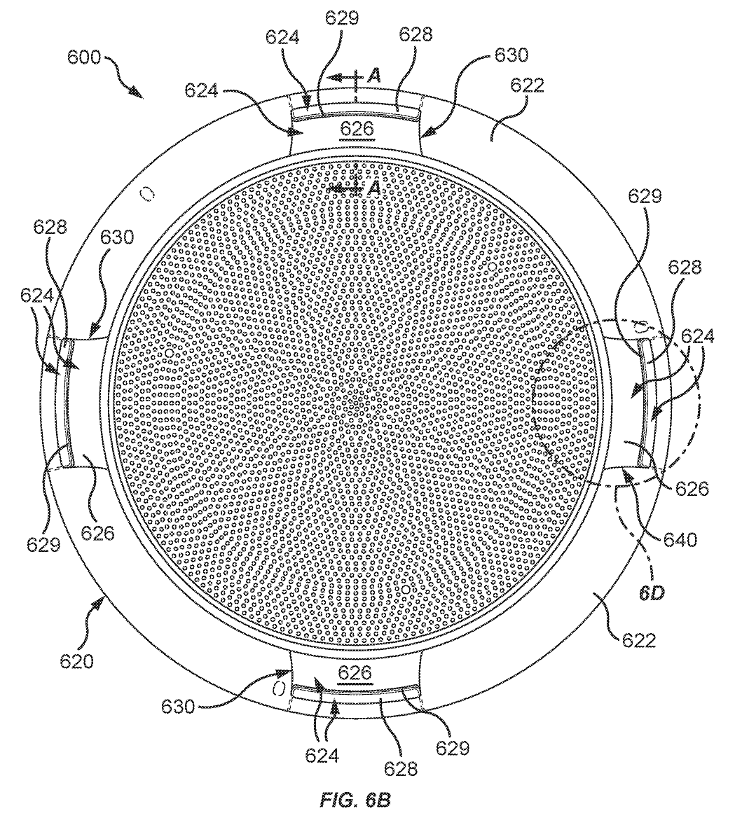

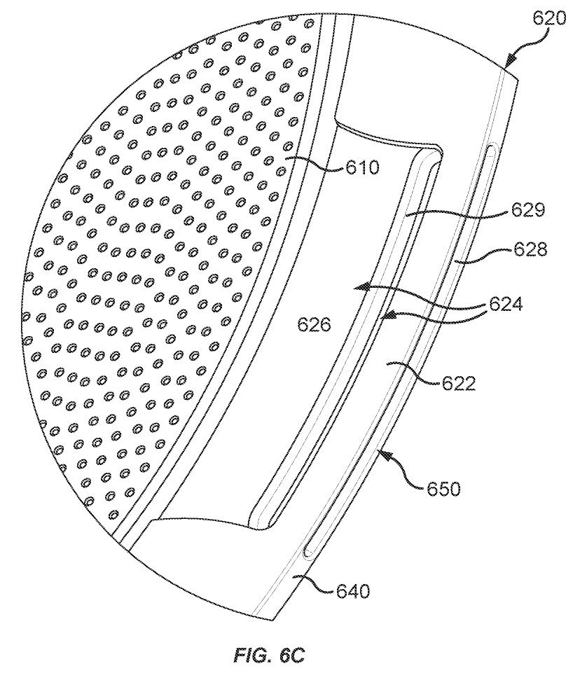

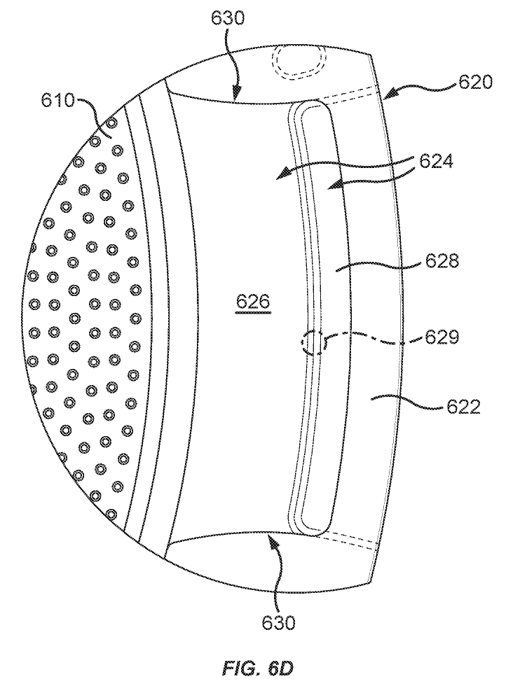

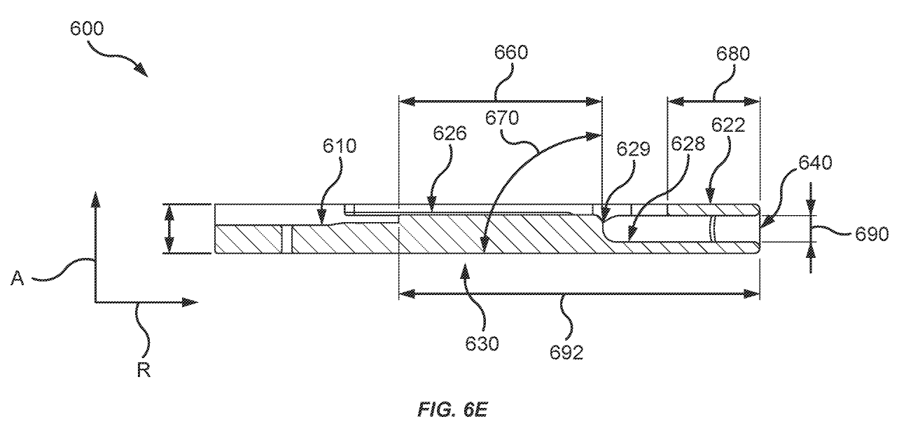

FIGS. 6A-6F depicts another susceptor 600 according to some embodiments of the present disclosure. The susceptor 600 defines a coordinate system including an axial direction A, a radial direction R, and a circumferential direction (not shown).

As illustrated in FIGS. 6A and 6B, the susceptor 600 includes a support surface 610 having a grid pattern. The susceptor 600 further includes a rim 620 extending around the periphery (e.g., outermost edge) of the support surface 610 and along the circumferential direction. As illustrated, the rim 620 defines a plurality of pockets 630 (e.g., recesses) spaced apart from one another along the circumferential direction of the susceptor 600. For instance, in some embodiments, the pockets 630 are spaced apart from one another by about 90 degrees along the circumferential direction.

As illustrated, each of the pockets 630 is defined by an upper portion 622 of the rim 620 and a lower portion 624 of the rim 620. More specifically, the upper portion 622 of the rim 620 may define a recess (e.g., cutout) at each of the corresponding pockets 630. The recess may expose at least a portion f the lower portion 624 of the rim 620. Furthermore, the lower portion 624 of the rim 620 includes a first portion 626, a second portion 628, and an intermediate third portion 629 (e.g., shelf) extending (e.g., along the axial direction) from the first portion 626 to the second portion 628 such that the first portion 626 is elevated (e.g., higher) relative to the second portion 628.

As illustrated, a peripheral surface 640 of the rim 620 may define a vent 650 at locations thereon corresponding to each of the respective pockets 630. In this manner, process gases and/or byproducts associated with processing a substrate may flow into a respective pocket 630 of the susceptor 600 and may flow along the lower portion 624 (e.g., first portion 626, second portion 628, third portion 629) and exit the respective pocket 630 via the vent 650.

As illustrated in FIG. 6E, a length 660 (e.g., measured along the radial direction) of the first portion 626 of the lower portion 624 of the rim 620 may range from 0.1 inches to 1.2 inches. In some embodiments, a slope 670 of the third portion 629 of the lower portion 624 of the rim 620 may range from 10 degrees to 90 degrees. In some embodiments, a length 680 of the pocket 630 (e.g., measured along the radial direction R) may range from 1 inch to 2 inches. In some embodiments, a length 680 of the upper portion 622 of the rim 620 that defines a ceiling of the respective pocket 630 may range from 0.2 inches to 1. 2 inches. Furthermore, in some embodiments, a height 690 of the respective pocket 630 from the floor (e.g., second portion 628 of the lower portion 624 of the rim 620) to the upper portion 622 of the rim 620 may range from 0.05 inches to 0.250 inches. In some embodiments, a length 692 (e.g, measured along the radial direction R) of the respective pocket 630 may range from 1 to 2 inches.

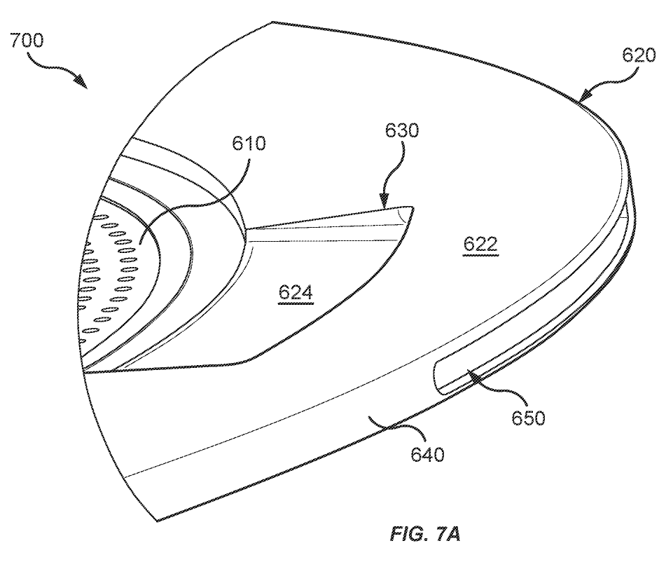

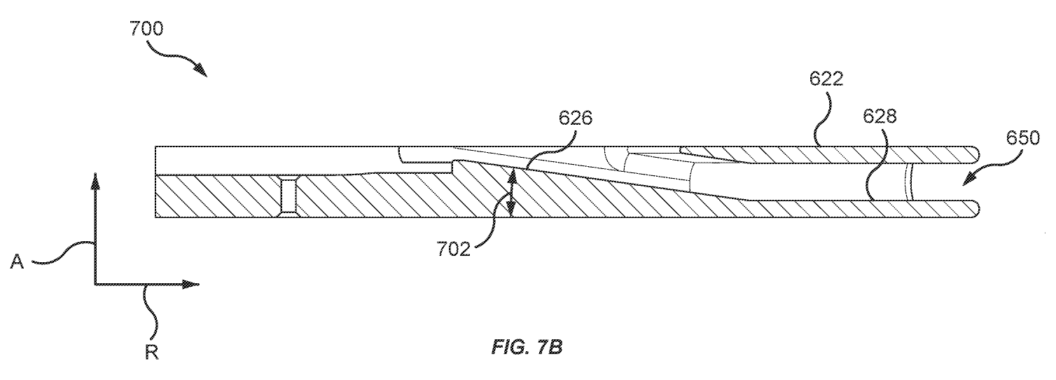

FIGS. 7A and 7B depict a susceptor 700 according to some embodiments of the present disclosure. The susceptor 700 is substantially similar to the susceptor 600 discussed above with reference to FIGS. 6A-6E and, for simplicity, reference numbers used to denote features of the susceptor 600 of FIGS. 6A-6E are reused for features of the susceptor 700 of FIGS. 7A and 7B that are the same. As illustrated, the lower portion 624 of the susceptor 700 in FIGS. 7A and 7B is different from the lower portion 624 of the susceptor 600 in FIGS. 6A-6E. More specifically, the lower portion 624 of the susceptor 700, specifically the first portion 626 thereof, may slope downward (e.g., along the radial direction R) towards the second portion 628 of the lower portion 624 of the susceptor 700 and, in contrast to the susceptor 600 of FIGS. 6A-6E, does not include a shelf (e.g., third portion 629). In some embodiments, a slope of the first portion 626 of the lower portion 624 of the susceptor 700 may be 10 degrees.

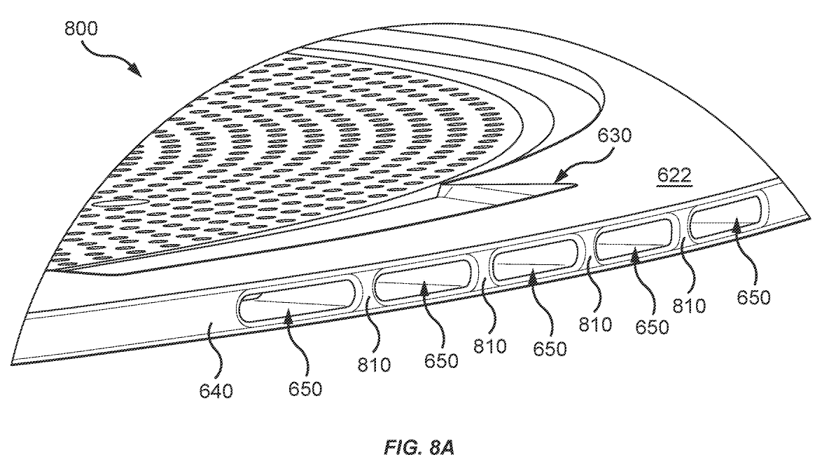

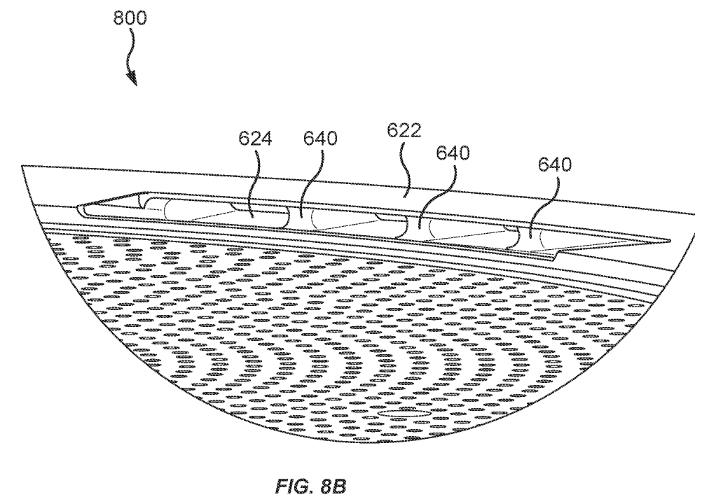

FIGS. 8A and 8B depict a susceptor 800 according to some embodiments of the present disclosure. The susceptor 800 is substantially similar to the susceptor 600 discussed above with reference to FIGS. 7A and 7B and, for simplicity, reference numbers used to denote features of the susceptor 700 of FIGS. 7A and 7B are reused for features of the susceptor 800 of FIGS. 8A and 8B that are the same.

As illustrated, the rim 620 of the susceptor 800 may define a plurality of ribs 810 extending (e.g., along the axial direction A) from the upper portion 622 of the rim 620 to the lower portion 624 of the rim 620. In this manner, the vent 650 may be divided into a plurality of vents 650 as shown. Also, the ribs 810 may reinforce the structural integrity of the rim 620 at the respective pocket 630.

While the foregoing is directed to specific embodiments, other and further embodiments may be devised without departing from the basic scope thereof, and the scope thereof is determined by the claims that follow.

1. A susceptor defining a coordinate system comprising an axial direction, a radial direction, and a circumferential direction, the susceptor comprising:
a support surface for a substrate; and
a rim extending around a periphery of the support surface, the rim defining a plurality of pockets spaced apart from one another along the circumferential direction, the rim further defining one or more vents at each respective pocket of the plurality of pockets.

2. The susceptor of claim 1, wherein the one or more vents comprise a plurality of vents, and wherein one or more vents of the plurality of the vents comprise:
a first opening defined in a first surface of the rim;
a second opening defined in a second surface of the rim that is perpendicular to the first surface; and
a gas channel extending from the first opening to the second opening.

3. The susceptor of claim 2, wherein the gas channel comprises:
a first portion extending from the first opening at an angle relative to the radial direction; and
a second portion extending from the first portion, the second portion being parallel to the radial direction.

4. The susceptor of claim 2, wherein:
the gas channel comprises a first gas channel; and
the one or more vents further comprise:
a third opening defined in the first surface, the third opening spaced apart from the first opening along the radial direction such that the third opening is closer to a periphery of the rim than the first opening; and
a second gas channel extending along the axial direction from the third opening in the first surface to the first gas channel.

5. The susceptor of claim 2, wherein the second opening is defined at a periphery of the susceptor.

6. The susceptor of claim 1, wherein each respective pocket of the plurality of pockets is defined between an upper surface of the rim and a lower surface of the rim that is spaced apart from the upper surface along the axial direction.

7. The susceptor of claim 6, wherein the lower surface of the rim comprises a first portion, a second portion, and a third portion extending along the axial direction from the first portion to the second portion.

8. The susceptor of claim 6, wherein the one or more vents comprise a single vent defined by a peripheral surface of the rim.

9. The susceptor of claim 8, further comprising a plurality of ribs extending from the upper surface to the lower surface along the axial direction to divide the single vent into a plurality of vents.

10. A processing chamber, comprising:
a chamber body in fluid communication with one or more gas sources; and
a substrate support assembly comprising a susceptor defining a coordinate system comprising an axial direction, a radial direction, and a circumferential direction, the susceptor comprising:
a support surface for a substrate; and
a rim extending around a periphery of the support surface, the rim defining a plurality of pockets spaced apart from one another along the circumferential direction, the rim further defining one or more vents at each respective pocket of the plurality of pockets.

11. The processing chamber of claim 10, wherein the one or more vents comprise a plurality of vents, and wherein one or more vents of the plurality of the vents comprise:
a first opening defined in a first surface of the rim;
a second opening defined in a second surface of the rim that is perpendicular to the first surface; and
a gas channel extending from the first opening to the second opening.

12. The processing chamber of claim 11, wherein the gas channel comprises:
a first portion extending from the first opening at an angle relative to the radial direction; and
a second portion extending from the first portion, the second portion being parallel to the radial direction.

13. The processing chamber of claim 12, wherein:
the gas channel comprises a first gas channel; and
the one or more vents further comprise:
a third opening defined in the first surface, the third opening spaced apart from the first opening along the radial direction such that the third opening is closer to a periphery of the rim than the first opening; and
a second gas channel extending along the axial direction from the third opening in the first surface to the first gas channel.

14. The processing chamber of claim 12, wherein the second opening is defined at a periphery of the susceptor.

15. The processing chamber of claim 11, wherein each respective pocket of the plurality of pockets is defined between an upper surface of the rim and a lower surface of the rim that is spaced apart from the upper surface along the axial direction.

16. The processing chamber of claim 15, wherein the lower surface of the rim comprises a first portion, a second portion, and a third portion extending along the axial direction from the first portion to the second portion.

17. The processing chamber of claim 16, wherein the one or more vents comprise a single vent defined by a peripheral surface of the rim.

18. The processing chamber of claim 17, further comprising:
a plurality of ribs extending from the upper surface to the lower surface along the axial direction to divide the single vent into a plurality of vents.

19. The processing chamber of claim 16, wherein the third portion of the lower surface extends at an angle relative to the axial direction, and wherein the angle ranges from 10 degrees to 90 degrees.

20. A processing system, comprising:
a processing chamber comprising:
a chamber body in fluid communication with one or more gas sources;
a substrate support assembly comprising a susceptor defining a coordinate system comprising an axial direction, a radial direction, and a circumferential direction, the susceptor comprising:
a support surface for a substrate; and
a rim extending around a periphery of the support surface, the rim defining a plurality of pockets spaced apart from one another along the circumferential direction, the rim further defining one or more vents at each respective pocket of the plurality of pockets.
